(19) United States
(12) Patent Application Publication
(10) Pub. No.: US 2026/0176131 A1
(43) Pub. Date: Jun. 25, 2026

(54) METHOD FOR BONDING A MEMS TO A SUBSTRATE

(71) Applicant: EXAIL, SAINT-GERMAIN-EN-LAYE (FR)

(72) Inventors: Pierrick CHEINEY, Saint-Germain-en-Laye (FR); Thomas KERRIEN, Saint-Germain-en-Laye (FR); Iannis ROLAND, Saint-Germain-en-Laye (FR); Karl AUBRY, Saint-Germain-en-Laye (FR)

(21) Appl. No.: 19/425,774

(22) Filed: Dec. 18, 2025

(30) Foreign Application Priority Data
Dec. 19, 2024 (FR) 2414730

(51) Int. Cl. B81C 1/00; B81B 7/00

(52) U.S. Cl. CPC B81C 1/00325; B81B 7/0058; B81C 2203/0109; B81C 2203/032; B81C 2203/0785

(57) ABSTRACT

The invention relates to a method for transferring a MEMS onto a substrate.

During the transferring method, an intermediate vibration absorption block (10) is interposed between the MEMS (20) and the substrate (8). The intermediate vibration absorption block (10) has such a minimum height that the distance between the MEMS (20) and the substrate (8) is higher than 100 μm. Advantageously, the dimensions of the intermediate vibration absorption block (10) are chosen with the aim of more effectively absorbing the mechanical vibrations from the substrate. The transferring method according to the invention thus makes it possible to increase the MEMS accuracy while limiting the risk of damage, or even breakage thereof, in particular when said MEMS is subjected to a vibratory environment of a few thousands of Hertz.

### TECHNICAL FIELD TO WHICH THE INVENTION RELATES

The present invention relates to the technical field of microelectronics and, more particularly, a method for transferring a MEMS onto a substrate.

### TECHNOLOGICAL BACKGROUND

The use of the micro-electromechanical systems, hereinafter called “MEMS”, has become commonplace in many different industries.

In the automotive industry, MEMS are used, for example, to detect sudden changes in the speed of a motor vehicle, in order to activate safety systems in the event of a collision.

In the aerospace field, MEMS are used to monitor in real time the direction and speed of travel of aircrafts, in order to allow, for example the guiding thereof by an on-board navigation system.

The above-mentioned MEMS have the distinctive feature of including mobile components to perform the above-mentioned measurements.

In order to preserve their integrity and to facilitate their integration into electronic devices, the MEMS are placed in sealed containers before their use. During this so-called encapsulation step, the MEMS are held in the bottom of a container by means of glue dots, then the container is sealed in order to maintain a controlled atmosphere around the MEMS. This results in a MEMS module, or “packaged MEMS”, which can be integrated into larger systems. Those larger systems may include electronic devices, integrated circuits and other components required to ensure the good operation as well as the communication of the MEMS with their environment.

The accuracy of the measurements made by the MEMS is largely due to the use of so-called sensitive parts, such as vibrating beams or test masses. These sensitive parts react to physical changes in their environment, transforming these changes into measurable signals. For example, the vibrating beams oscillate at a specific frequency that changes as a function of the forces applied, thus enabling the detection of accelerations or rotations. The test masses, meanwhile, move in response to the MEMS movements, and their relative position can be measured with a great accuracy to determine the orientation or acceleration of a device comprising the MEMS. The sensitivity of these components to the slightest variations makes them particularly effective for high-accuracy measurements, but also make them vulnerable to parasitic disturbances.

Such parasitic disturbances include in particular the mechanical vibrations transmitted to the MEMS by the container in which they are sealed. Such mechanical vibrations then propagate to the sensitive parts of the MEMS, distorting the measurements made by the MEMS, preventing the detection of low-intensity signals or, worse still, causing premature and irreversible damage to these sensitive parts.

In order to increase the performances as well as the life duration of the MEMS, it is therefore desirable to attenuate this phenomenon of parasitic disturbance propagation to the MEMS.

To achieve this objective, the use of so-called decoupling frames is well known. Such decoupling frames are interposed between the MEMS and their substrate in order to attenuate this phenomenon of parasitic disturbance transmission between MEMS and their substrate.

Nevertheless, the decoupling frames have the disadvantage of having their own mechanical resonance modes, typically of a few Kilohertz, for example of the order of 2.6 KHz. An external vibration at the vibration frequency of a natural mechanical mode of a decoupling frame may then be amplified by said decoupling frame. The amplification phenomenon may correspond to the quality factor of the mechanical mode in question, which can reach amplification levels of several thousands.

The invention aims to propose a solution making it possible to limit the risk of damage, or even breakage of the sensitive part of a MEMS, due to the transmission of mechanical vibrations between said MEMS and the substrate thereof, in particular when the mechanical vibrations are of the order of a few thousands of Hertz.

### OBJECT OF THE INVENTION

In order to achieve the above-mentioned objective, the invention proposes a method for transferring a MEMS onto a substrate, wherein the MEMS is fastened onto the substrate.

The invention is remarkable in that an intermediate vibration absorption block is interposed between the MEMS and the substrate, and in that the intermediate vibration absorption block has such a minimum height that the distance between the MEMS and the substrate is higher than 100 μm.

Advantageously, when the intermediate vibration absorption block keeps a distance higher than 100 μm between the MEMS and substrate, the mechanical vibrations of the substrate and/or the mechanical vibrations of the MEMS are more efficiently absorbed by the intermediate vibration absorption block, in particular when the frequencies of the mechanical vibrations are of the order of a few thousands of Hertz.

The transferring method proposed by the invention thus enables to limit the risk of damage or breakage of the MEMS when the MEMS is held to a substrate vibrating at frequencies of the order of a few thousands of Hertz.

According to another advantage, by absorbing the vibrations of the substrate and/or the vibrations of the MEMS, the intermediate vibration absorption block significantly limits the influence of these vibrations on the MEMS operation. The MEMS is therefore capable of making measurements of better quality in frequency ranges of the order of a few thousands of Hertz. In other words, the mechanical vibrations of the substrate and/or the mechanical vibrations of the MEMS are less likely to distort or degrade the MEMS sensitivity in ranges of natural resonance modes of the MEMS.

By “natural resonance mode of the MEMS”, it is meant one or several frequencies for which at least one sensitive part of a MEMS, comprising for example a mobile element and/or an oscillating element, is able to vibrate and potentially enter into resonance.

The transferring method described hereinabove thus enables to increase the MEMS performances as well as longevity thereof.

According to another embodiment of the invention, the intermediate vibration absorption block has such a minimum height that the distance between the MEMS and the substrate is higher than 200 μm, preferably between 250 μm and 500 μm, or of the order of 275 μm.

According to another embodiment of the invention, the intermediate vibration absorption block has a first side facing the substrate and second side facing the MEMS, the smallest dimension of each of these two sides being equal to or higher than 300 μm, preferably between 400 μm and 600 μm, or of the order of 500 μm.

Advantageously, an intermediate vibration absorption block having a minimum height as well as a smallest dimension at its first and its second side, selected in the above-mentioned ranges of values, enables a better absorption of the mechanical vibrations of the substrate when said vibrations are included in a range of frequencies from 1,000 Hz to 10,000 Hz, preferably from 2,500 Hz to 2,700 Hz or of the order of 2,600 Hz.

According to another embodiment of the invention, the first side and/or the second side of the intermediate vibration absorption block has a circular or substantially circular outline. An intermediate absorption block with this shape offers the advantage of being achievable through methods that are easier to implement and therefore more economical.

According to a preferred embodiment, the block has a prismatic or cylindrical shape. These shapes have the advantage of being easier and quicker to produce by implementing a layer cutting method, as described hereafter, by implementing a punching method.

According to another embodiment of the invention, the transferring method implements the following steps:
a) depositing a first layer of adhesive material onto the substrate; then
b) depositing the intermediate vibration absorption block onto the first layer of adhesive material, the first side of the intermediate vibration absorption block coming into direct contact with said first layer; then
c) depositing a second layer of adhesive material onto the second side of the intermediate vibration absorption block; then
d) putting the MEMS into contact with the second layer of adhesive material.

According to another advantage of the invention, the transferring method enables to maintain a MEMS at a greater distance from its substrate, using a smaller amount of adhesive material. Indeed, contrary to the known transferring methods of the prior art, the adhesive material is not used for the purpose of holding the MEMS away from its substrate, but to hold an intermediate vibration absorption block between the MEMS and its substrate. That way, the thickness, and hence the amount of adhesive material used during the transferring method, is far smaller with respect to the transferring methods proposed by the state of the art.

According to another advantage, the use of a smaller amount of adhesive material significantly reduces the time and/or temperature of a heat treatment implemented after the transferring method, for example during a step e), to allow satisfactory polymerisation of the layers of adhesive material holding the intermediate vibration absorption block between the MEMS and the substrate thereof. The invention thus allows time and resource saving when transferring a MEMS onto a substrate.

According to another advantage, when a heat treatment is implemented, after the transferring method, the phenomenon of degassing from the layers of adhesive material is significantly reduced, due to a smaller amount of adhesive material used, as mentioned hereinabove. The risks of adhesive material compounds dissipating into the environment are therefore significantly reduced. By limiting this degassing phenomenon, the invention also enables to reduce the presence at the MEMS surface of compounds issuing from the adhesive material used for it to be held on a substrate, liable to degrade or even prevent the MEMS operation.

Preferably, the thickness of the first layer and/or the thickness of the second layer of adhesive material is equal to or less than 20 μm, preferably between 1 μm and 10 μm.

The first layer of adhesive material can be composed of a synthetic polymer comprising silicon, preferably the first layer of adhesive material is silicone-based. The second layer of adhesive material may be identical or substantially identical to the first layer of adhesive material.

According to another embodiment of the invention, the MEMS can be held to the substrate by means of several intermediate vibration absorption blocks, interposed or inserted between the substrate and the MEMS. The intermediate vibration absorption blocks have the same characteristics or substantially the same characteristics as the intermediate vibration absorption block described hereinabove.

In other words, the steps a) to c) of the above-described transferring method, enabling the interposition of an intermediate vibration absorption block between the substrate and the MEMS, can be reproduced so that several intermediate vibration absorption blocks are present between the MEMS and the substrate.

According to another embodiment of the invention, an intermediate vibration absorption block according to the invention is chosen so that the smallest distance between the first side and the second side of said block is equal to or higher than 100 μm, equal to or higher than 200 μm, or preferably between 250 μm and 500 μm, or of the order of 275 μm.

According to another embodiment of the invention, the intermediate vibration absorption block has a form factor included between 0.2 and 1, preferably between 0.3 and 0.7. By “form factor”, it is meant the result of a ratio between the minimum height value of the intermediate vibration absorption block, corresponding to the smallest distance between its first side and its second side, and the greatest dimension value of the first side. Preferably, a high value form factor will be chosen when an increased attenuation of at least one natural resonance mode of the MEMS is desired.

According to another embodiment of the invention, the second side of the intermediate vibration absorption block is parallel or substantially parallel to its first side. This embodiment advantageously enables the use, for example, of a disc created by punching a layer, as an intermediate vibration absorption block.

According to another embodiment of the invention, the Young's module value of the intermediate vibration absorption block is between 5 MPa and 10 MPa, preferably between 6 MPa and 9 MPa.

According to another embodiment of the invention, the intermediate vibration absorption block is produced using a punching method.

Preferably, the intermediate vibration absorption block is produced by a punching or die-cutting method. This type of method has for advantage to enable the production of intermediate vibration absorption blocks whose shape and dimensions are controlled, far more accurately than with a polymerized layer of adhesive material.

According to another advantage, the making of an intermediate vibration absorption block by a punching method enables the production of plots with an aspect ratio that cannot be achieved by depositing adhesive material on a substrate. In other words, a punching method enables the making of intermediate vibration absorption blocks having height and width that cannot be obtained by depositing adhesive material on a substrate. That way, the blocks obtained by this method have different absorption properties with respect to the layers of adhesive material used to hold a MEMS on a substrate. The making of intermediate vibration absorption blocks by a punching method thus enables the making of blocks with the above-mentioned dimensions, having for advantage to offer a better attenuation of the thermomechanical stress and a greater reduction of the quality factor of low-frequency resonance modes, in particular in the above-mentioned frequency ranges.

According to another advantage, the making of intermediate vibration absorption blocks by punching or die-cutting of a layer enables faster, simpler and highly reproducible production of blocks. The making of one or several intermediate vibration absorption blocks by a punching method also enables the automation of the transferring method described above, thereby significantly reducing costs.

According to another advantage, the punching enable intermediate vibration absorption blocks to be made from dies that are less likely to contaminate the MEMS, for example during the degassing phenomenon described hereinabove.

According to another advantage, the intermediate vibration absorption block is composed of a synthetic polymer comprising silicon, preferably said block is silicone-based.

According to another embodiment of the invention, the MEMS is a resonating MEMS or a capacitive MEMS. By “resonating MEMS”, it is meant a MEMS comprising at least one element capable of oscillating, whose oscillation frequencies are measured to characterise a physical phenomenon. By way of non-limiting example, a resonating MEMS is adapted to perform the following measurements: acceleration, rotation, mass detection.

Obviously, the different features, alternatives and embodiments mentioned hereinabove can be associated with each other according to various combinations, insofar as they are not incompatible or exclusive with respect to each other.

The invention also relates to a MEMS encapsulation method, implementing a transferring method as described hereinabove.

By way of non-limiting example, following a transferring method as described hereinabove, the encapsulation method can implement a step of positioning a hollow casing on the substrate, so that the MEMS held to the substrate by means of at least one intermediate vibration absorption block is protected from the external environment by said casing.

According to an alternative embodiment, the encapsulation method can implement a method according to the invention of transferring a MEMS into a casing, then a step of sealing said casing with a lid, so that the MEMS is isolated from the environment outside the casing.

According to a preferred embodiment, at the end of an encapsulation method as described hereinabove, a MEMS module comprising a MEMS in a sealed and/or hermetic casing is obtained.

The invention also relates to a MEMS module comprising at least one MEMS encapsulated into a casing and attached to a substrate. The MEMS module is remarkable in that it includes at least one intermediate vibration absorption block, interposed between the MEMS and the substrate.

According to another embodiment of the invention, at least one intermediate vibration absorption block has such a minimum height that the distance between the MEMS and the substrate is higher than 100 μm. For the above-mentioned reasons, at least one intermediate vibration absorption block has a minimum height that is equal to or higher than 200 μm, preferably between 250 μm and 500 μm, or of the order of 275 μm.

According to another embodiment of the invention, at least one intermediate vibration absorption block has a first side facing the substrate and a second side facing the MEMS. The smallest dimension of the first side may be equal to or higher than 300 μm, preferably between 400 μm and 600 μm. The smallest dimension of the second side may be equal to or higher than 300 μm, preferably between 400 μm and 600 μm.

According to another embodiment of the invention, a first layer of adhesive material is present between the substrate and said at least one intermediate vibration absorption block.

According to another embodiment of the invention, a second layer of adhesive material is present between at least one intermediate vibration absorption block and the MEMS.

Preferably, the Young's modulus value of at least one intermediate vibration absorption block is between 5 MPa and 10 MPa, preferably between 6 MPa and 9 MPa.

According to another embodiment of the invention, a wall of the MEMS module is formed by the substrate.

Preferably, one or several intermediate vibration absorption blocks present between the substrate and the MEMS are identical or substantially identical to the intermediate vibration absorption block used during the implementation of a transferring method described hereinabove.

According to another embodiment, the Young's module value of at least one intermediate vibration absorption block is between 5 MPa and 10 MPa, preferably between 6 MPa and 9 MPa.

According to another embodiment, at least one intermediate vibration absorption block is composed of a synthetic polymer comprising silicon. Preferably, at least one intermediate vibration absorption block is silicone-based.

According to another embodiment, at least one intermediate vibration absorption block is produced using a punching method.

### DESCRIPTION OF THE FIGURES

The invention will be better understood, thank to the following description, which relate to preferred embodiments, given by way of non-limiting examples, and explained with reference to the attached schematic drawings, in which:

FIG. 1 shows a first step of a method for transferring a MEMS onto a substrate, according to the invention, consisting in depositing a first layer of adhesive material at the surface of the substrate;

FIG. 2 shows a second step of the transferring method according to the invention, consisting in positioning an intermediate vibration absorption block onto the first layer of adhesive material;

FIG. 3 shows a third step of the transferring method according to the invention, consisting in depositing a second layer of adhesive material onto the intermediate vibration absorption block;

FIG. 4 shows a fourth step of the transferring method according to the invention, consisting in positioning a MEMS onto the second layer of adhesive material;

FIG. 5 shows a first step of making an intermediate vibration absorption block according to the invention, by implementing a punching method;

FIG. 6 shows a second step of the punching method, consisting is moving the punch visible in FIG. 5 through a die to obtain an intermediate vibration absorption block;

FIG. 7 shows a third step of the punching method, consisting in positioning the punch facing a first layer of adhesive material covering a substrate;

FIG. 8 shows a fourth step of the punching method, consisting in extracting the intermediate vibration absorption block from the punch so that said block is in contact with the first layer of adhesive material;

FIG. 9 shows a diagram in which can be found several damping factor simulations, carried out using modelling of test devices, each test device comprising a MEMS held to a substrate of same nature, by a same transferring method according to the invention, the sizes of the intermediate vibration absorption blocks holding the MEMS to its substrate being different for each test device;

FIG. 10 shows a schematic cross-section of a MEMS module obtained by a transferring method according to the invention.

### DETAILED DESCRIPTION OF THE INVENTION

As a reminder, the invention proposes a method for transferring a MEMS onto a substrate, enabling to significantly attenuate the MEMS vibrations for at least one natural resonance mode of the MEMS.

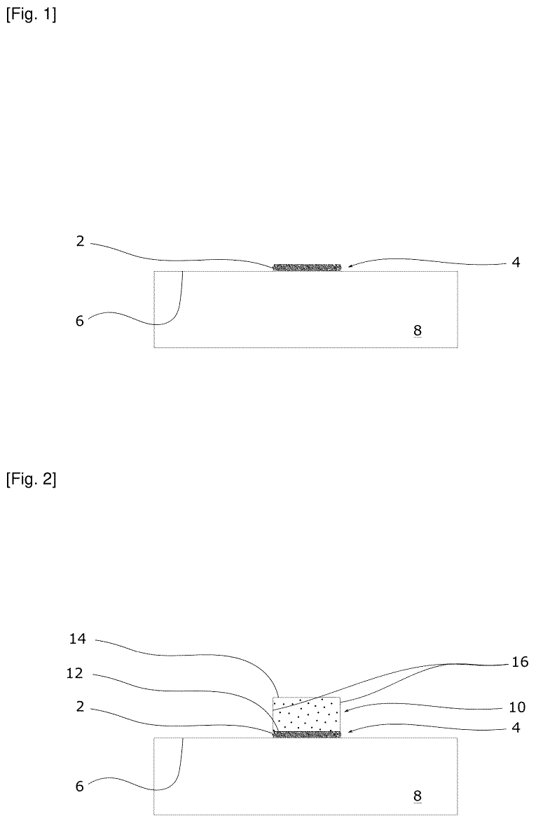

A non-limiting embodiment of a method for transferring a MEMS onto a substrate according to the invention is illustrated in FIGS. 1 to 4 hereinafter.

According to a first step illustrated by FIG. 1, an adhesive material 2 is deposited in the form of a first layer 4, onto a first side 6 of a substrate 8. Preferably, the first side 6 of the substrate is planar or substantially planar. The substrate may be composed of a metallic material and/or a ceramic material. In the present case, the substrate 8 is a ceramic.

According to the present example, the adhesive material 2 is deposited by dabbing. This deposition method advantageously enables a thin first layer 4 of adhesive material to be formed on the first side 6 of the substrate. By “thin”, it is meant a thickness of between 1 μm and 10 μm. The thickness of the first layer 4 is measured along a direction normal or substantially normal to the first side 6 of the substrate.

It is to be noted that, in order to facilitate the understanding of the invention, the elements shown in the figures are not to scale.

The surface area of the first side 6 of the substrate, covered by the first layer 4 is chosen according to the dimensions of an intermediate vibration absorption block that is desired to be held to the substrate 8, as described hereinafter. The first layer 4 can for example cover a surface of the first side 6 that is between 0.05 mm² and 0.2 mm².

The adhesive material 2 forming the first layer 4 may be composed of a synthetic polymer comprising silicon, preferably silicone.

According to a second step illustrated by FIG. 2, an intermediate vibration absorption block 10 is superimposed to the first layer 4, so that a first side 12 of said block, also called lower side, faces the first side 6 of the substrate and is in contact with the adhesive material 2. Preferably, the totality of the lower side of the intermediate vibration absorption block is in contact with the adhesive material.

The intermediate vibration absorption block 10 is delimited by a second side 14, also called upper side, opposite to its lower side. Preferably, the lower side is planar, the upper side is parallel or substantially parallel to the lower side. The height of the intermediate vibration absorption block, corresponding to the smallest distance between its lower side and its upper side, is equal to or higher than 100 μm, or equal to or higher than 200 μm, or preferably between 250 μm and 300 μm, or of the order of 275 μm.

The intermediate vibration absorption block is characterized by a form factor of between 0.2 and 1. By the expression “form factor”, it is meant the result of a ratio between the height value of the intermediate vibration absorption block and its width value. The intermediate vibration absorption block width corresponds to the smallest distance measured between the opposite lateral sides 16 of said block and along a direction parallel to its lower side 12. The width of the intermediate vibration absorption block may be between 250 μm and 500 μm.

According to the present example, the block 10 is cylindrical in shape and its diameter is of the order of 500 μm.

The intermediate vibration absorption block 10 is composed of a material whose Young's module value is between 5 MPa and 10 MPa. The Young's module measurement is based on the measurements of damped resonance modes, performed using the instrument marketed by WATERS under the reference “ElectroForce 3200”.

At the end of the second step, the intermediate vibration absorption block 10 is held by the adhesive material 2 to the first side 6 of the substrate and extends perpendicular or substantially perpendicular to said first side 6.

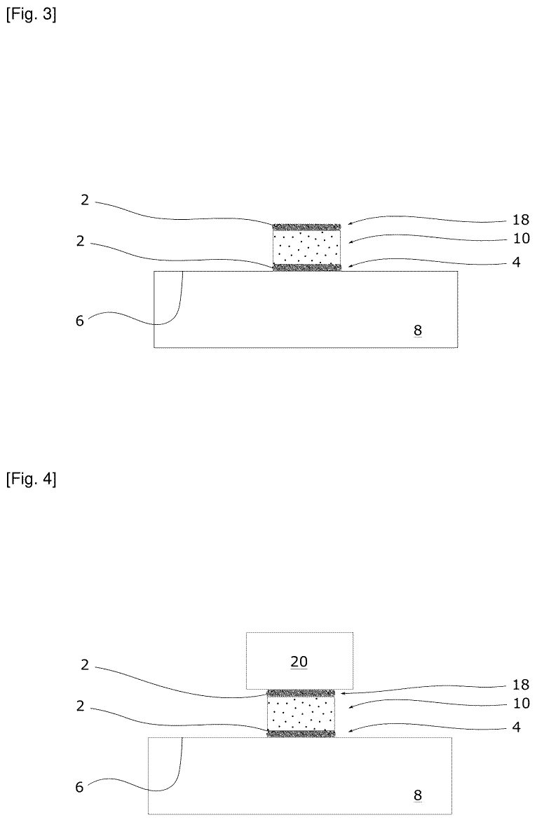

According to a third step illustrated in FIG. 3, an adhesive material 2 is deposited on the upper side of the intermediate vibration absorption block 10, as a second layer 18. Preferably, the second layer 18 is composed of the same material or substantially the same material as the first layer 4 and the second layer 18 is deposited according to the same method as the first layer 4. The second layer 18 has preferably a thickness identical or substantially identical to that of the above-described first layer 4. Preferably, the second layer 18 covers the whole upper side of the intermediate vibration absorption block 10.

According to a fourth step illustrated in FIG. 4, a MEMS 20 is deposited onto the second layer 18, so that the MEMS is supported by the intermediate vibration absorption block 10.

Possibly, according to a fifth step not illustrated, the unit obtained at the end of the fourth step can be heat treated to promote faster and better polymerisation of the first layer 4 and the second layer 18 of adhesive material. By way of non-limiting example, the heat treatment is of the order of 150° C. during a time duration of the order of one hour.

Advantageously, the transferring method according to the invention enables to hold the MEMS 20 away from the first side 6 of the substrate, with a significantly less adhesive material compared to the prior art. The presence of the intermediate vibration absorption block 10 between the substrate 8 and the MEMS 20 indeed enables significant savings in adhesive material, which is usually used to maintain a certain distance between the MEMS and the substrate.

The invention therefore enables substantial savings in adhesive material, when transferring a MEMS onto a substrate.

Another advantage is that, because less adhesive material is used, the risk of compounds from the adhesive material being released into the environment is significantly reduced. The invention thus minimises the risk of environmental pollution of the MEMS by the adhesive material.

Interposing an intermediate vibration absorption block 10 between the substrate 8 and the MEMS 20 advantageously enables to damp certain vibration modes of the MEMS. Advantageously, the dimensions and shape of the intermediate vibration absorption block 10 can be selected to significantly attenuate or damp the natural vibration modes of the MEMS.

By “natural vibration mode”, it is meant a vibration of the MEMS at a specific frequency at which the MEMS vibrates and/or oscillates under the effect of an external excitation.

The transferring method according to the invention is particularly advantageous when it is desired to minimize or at least attenuate a natural vibration mode of a resonating MEMS, liable to degrade or distort the measurements taken by the MEMS.

According to an alternative embodiment, not shown, of the above-mentioned transferring method, each step can be reproduced several times so that a MEMS can be held to a substrate, using several blocks identical or substantially identical tot he intermediate vibration absorption block 10.

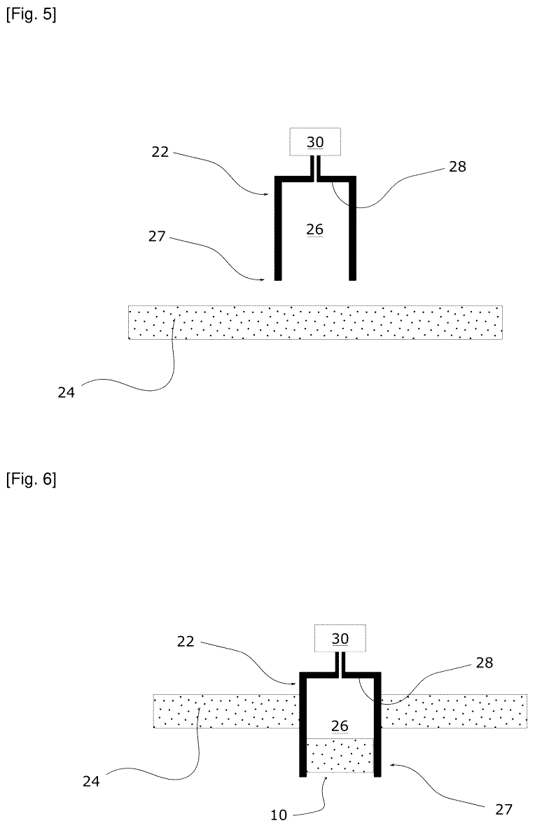

Preferably, the intermediate vibration absorption block 10 is produced by a punching method whose steps are illustrated by the appended FIGS. 5 to 8.

FIG. 5 shows a first step of the punching method according to the invention, consisting in placing a punch 22 opposite a die 24. The die 24 is preferably a layer whose thickness is identical or substantially identical to the height of the above-described intermediate vibration absorption block 10.

The punch 22 delimits a cavity 26 with a complementary shape to that of the block 10 that is desired to be obtained. According to the present example, the cavity delimits a volume of cylindrical shape. The cavity 26 is open at a first end 27 facing the die 24. The cavity height is sufficient to allow a cut to be made in the die when the punch 22 passes through the die, as illustrated in FIG. 6.

After the punch has moved through the die 24, a block 10 is present in the cavity 26 of the punch 22.

Advantageously, the bottom 28 of the cavity is connected to suction means 30, so as to ensure that the intermediate vibration absorption block 10 is held within the cavity when the punch 22 is moved.

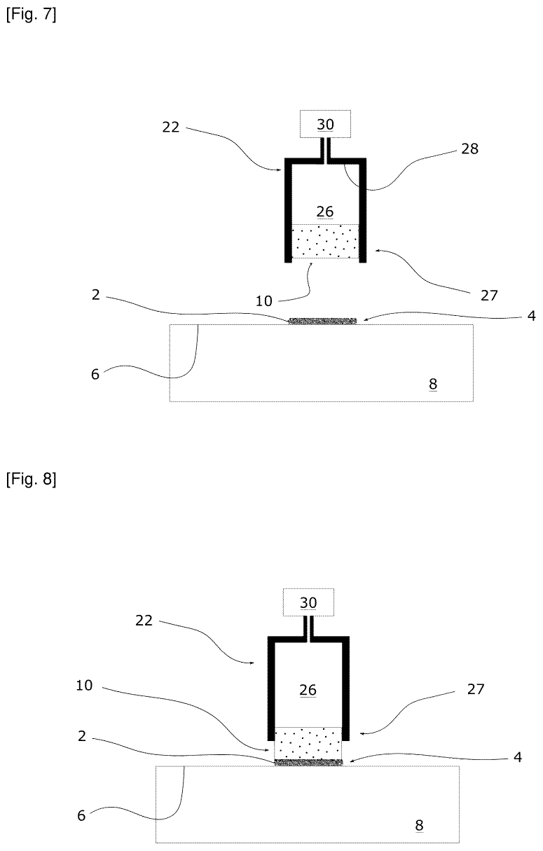

As illustrated in FIG. 7, the punch 22 can be used to position the intermediate vibration absorption block 10 opposite the first layer 4 of adhesive material, during the second step of the transferring method described hereinabove.

In order to facilitate the extraction of the intermediate vibration absorption block 10 from the cavity 26 of the punch during the positioning of the intermediate vibration absorption block 10 on the first layer 4, the suction means 30 can be disconnected from the cavity. According to an alternative embodiment, the suction means 30 can be inverted so as to increase the atmospheric pressure in the bottom of the cavity and allow the intermediate vibration absorption block 10 to be expelled from said cavity, as illustrated in FIG. 8.

The punch 22 can then be moved from the substrate 8 to be able to implement the third step of the transferring method according to the invention, illustrated by FIG. 3.

In other words, the punch 22 can also be used as a tool for moving and positioning the intermediate vibration absorption block 10 during a MEMS transferring method as proposed by the invention.

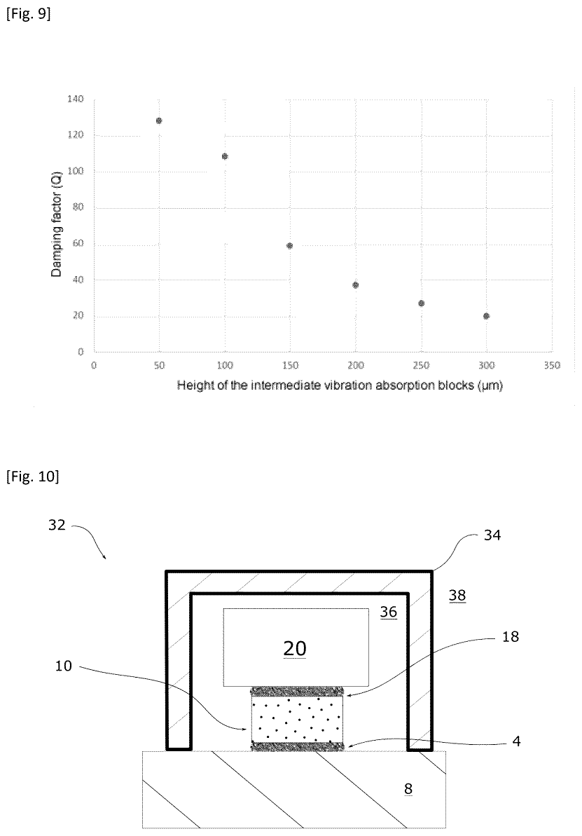

By way of non-limiting example, the table 1 hereinafter, as well as the appended FIG. 9, show the results of finite element simulations: damping factors depending on the height of the intermediate vibration absorption blocks. The theoretical finite element model was validated by measurements taken on several test devices with intermediate vibration absorption block heights of 100 μm and 250 μm.

Each test device is composed of a same MEMS held to a same substrate by a same transferring method, as described hereinabove.

TABLE 1

| Intermediate vibration | Amplification |
|---|---|
| absorption block height (μm) | factor (Q) |
| 50 | 128 |
| 100 | 108 |
| 150 | 59 |
| 200 | 37 |
| 250 | 27 |
| 300 | 20 |

More precisely, each MEMS is held to its substrate by a same number of intermediate vibration absorption blocks. The intermediate vibration absorption blocks have the same shape and are arranged in a same way between the MEMS and its substrate.

The measurements are made by applying at the substrate of each test device, by know means, a mechanical vibration whose frequency is equal or substantially equal to the resonance frequency of the first mechanical mode of the MEMS, in the present case of the order of 2.6 KHz. The amplification factor (Q) is determined by calculating the ratio between the vibration amplitude observed at the sensitive element (inside the decoupling frame that enters into resonance), and the vibration amplitude applied.

More specifically, the tests performed are spectroscopy tests, i.e. an excitation frequency is applied to each test device, and said excitation frequency is modulated around a resonance frequency of the order of 2.6 kHz, so as to observe a significant amplification of the resonance frequency, hereinafter referred to as the “resonance peak”. The amplitude as well as the width of the resonance peak enable to determine the amplification factor (Q) as described hereinabove.

The excitation applied to the devices was achieved by applying a mechanical excitation. For that purpose, each test device is positioned on a vibrating pot that applies mechanical excitation within a desired frequency range, in the present case about 2.6 kHz. The damping factor measurements are obtained based on the acceleration measurements at the sensitive elements of the MEMS.

As illustrated by Table 1 and FIG. 9, the implementation of the invention advantageously makes it possible to significantly reduce the value of the amplification factor of a test device, when the height of the intermediate vibration absorption blocks holding the MEMS to its substrate increases. The invention thus makes it possible to control precisely the value of the damping factor of a test device and thus of a MEMS module, in a more accurate and more efficient way, to improve the sensitivity of the measurements taken by the MEMS, and also to increase the lifetime thereof.

The invention also relates to a MEMS module 32 as illustrated by the appended FIG. 10. In the present example, the MEMS module 32 is obtained using a transferring method as described hereinabove.

The MEMS module 32 is thus made of a substrate 8 on which a MEMS 20 is held, by means of at least one intermediate vibration absorption block 10 and adhesive layers 4 and 18 described hereinabove.

The MEMS module 32 also comprises a casing 34 delimiting a hollow space 36. The casing 34 is held opposite the substrate 8, preferably against said substrate, so that the MEMS is present in the space 36 delimited by said casing.

The casing is preferably held against said substrate so as to protect the MEMS 20 from the external environment 38. The MEMS module can be hermetic and/or sealed off from the external environment 38.

1. A method for transferring a MEMS onto a substrate, wherein the MEMS is fastened onto the substrate, characterized in that an intermediate vibration absorption block is interposed between the MEMS and the substrate, and in that the intermediate vibration absorption block has such a minimum height that the distance between the MEMS and the substrate is higher than 100 μm.

2. The transferring method according to claim 1, wherein the intermediate vibration absorption block has a first side facing the substrate and second side facing the MEMS, the smallest dimension of each of these two sides being equal to or higher than 300 μm.

3. The transferring method according to claim 2, implementing the following steps:
a) depositing a first layer of adhesive material onto the substrate; then
b) depositing the intermediate vibration absorption block onto the first layer of adhesive material, the first side of the intermediate vibration absorption block coming into direct contact with said first layer; then
c) depositing a second layer of adhesive material onto the second side of the intermediate vibration absorption block; then
d) putting the MEMS into contact with the second layer of adhesive material.

4. The transferring method according to claim 2, wherein the smallest distance between the first side and the second side of the intermediate vibration absorption block is equal to or higher than 100 μm.

5. The transferring method according to claim 1, wherein the Young's module value of the intermediate vibration absorption block is between 5 MPa and 10 MPa.

6. The transferring method according to claim 1, wherein the intermediate vibration absorption block is produced by a punching method.

7. The transferring method according to claim 1, wherein the MEMS is of the resonating or capacitive type.

8. A method for encapsulating a MEMS implementing a transferring method according to claim 1.

9. A MEMS module comprising at least one MEMS encapsulated in a casing and attached to a substrate, characterized in that it includes at least one intermediate vibration absorption block interposed between the MEMS and the substrate.

10. The MEMS module according to claim 9, wherein said at least one intermediate vibration absorption block has such a minimum height that the distance between the MEMS and the substrate is higher than 100 μm.

11. The MEMS module according to claim 9, wherein said intermediate vibration absorption block has a first side facing the substrate and second side facing the MEMS, the smallest dimension of each of these two sides being equal to or higher than 300 μm.

12. The MEMS module according to claim 9, wherein a first layer of adhesive material is present between the substrate and said at least one intermediate vibration absorption block.

13. The MEMS module according to claim 9, wherein the Young's module value of the intermediate vibration absorption block is between 5 MPa and 10 MPa.

14. The MEMS module according to claim 9, wherein said at least one intermediate vibration absorption block is composed of a synthetic polymer comprising silicon.

15. The MEMS module according to claim 9, wherein said at least one intermediate vibration absorption block is produced by a punching method.
